(19) United States
(12) Patent Application Publication
(10) Pub. No.: US 2026/0015749 A1
(43) Pub. Date: Jan. 15, 2026

(54) ELECTRODE MODULE HAVING POSITIVE ELECTRODE AND NEGATIVE ELECTRODE, AND S-ECAM PRINTING DEVICE COMPRISING SAME

(71) Applicant: ANYCASTING CO., LTD., Seoul (KR)

(72) Inventors: Sungbin KIM, Seoul (KR); Kunwoong KO, Seoul (KR); Myungjun KIM, Seoul (KR); Moonsu SHIN, Seoul (KR)

(73) Assignee: ANYCASTING CO., LTD., Seoul (KR)

(21) Appl. No.: 18/995,849

(22) PCT Filed: Apr. 26, 2023
(86) PCT No.: PCT/KR2023/005671

§ 371 Date: Jan. 17, 2025

(30) Foreign Application Priority Data
May 31, 2022 (KR) 10-2022-0067242

(51) Int. Cl. C25D 1/00; B33Y 30/00; B33Y 50/02; H05K 3/30

(52) U.S. Cl. CPC C25D 1/003; B33Y 30/00; B33Y 50/02; H05K 3/305

(57) ABSTRACT

The present invention relates to a selective electrochemical additive manufacturing (S-ECAM) printing device which can selectively deposit metal raw materials on a substrate using electrochemical additive manufacturing (ECAM). In addition, the present invention relates to an S-ECAM printing device which can form a adhesion layer for mounting a chip on a circuit board without using a mask.

### TECHNICAL FIELD

The present disclosure relates to a selective electrochemical additive manufacturing (S-ECAM) printing device, and more particularly, to an S-ECAM printing device for selectively depositing a metal raw material on a substrate by using electrochemical additive manufacturing (ECAM).

### BACKGROUND

Korean Patent No. 10-2392201 (3D printing device using selective electrochemical deposition having a multi-electrode module), Korean Patent No. 10-2392199 (Control method for 3D printing device using selective electrochemical deposition), and Korean Patent No. 10-2382806 (3D printing device using selective electrochemical deposition performing gap control using pulse peak) disclose 3D printing devices using selective electrochemical deposition.

FIG. 1 is a diagram showing a conventional 3D printing device using selective electrochemical deposition, and FIG. 2 is a diagram showing a state in which power is applied to a substrate and an electrode.

Referring to FIGS. 1 and 2, a conventional 3D printing device 10 using selective electrochemical deposition includes a tub 20 that accommodates electrolyte 11, a substrate 12 that is placed while being immersed in the electrolyte 11 accommodated in the tub 20, a multi-electrode module 30 having an electrode holder 31 and a plurality of electrodes 32 that are arranged and fixed at a predetermined interval to the electrode holder 31, a driver 13 that controls movement of the multi-electrode module 30, a power supply 50 that supplies power to the substrate 12 and the plurality of electrodes 32, and a controller 14 that controls the driver 13 and the power supply 50 to selectively electrochemical-deposit and stack metal ions included in the electrolyte 11 on the substrate 12.

The substrate 12 and bottom surfaces 33 of the plurality of electrodes 32 may be immersed in the electrolyte 11 accommodated in the tub 20 while facing each other and spaced apart from each other by a predetermined distance.

For example, the substrate 12 may be immersed in the electrolyte 11 accommodated in the tub 20 while placed on a support 21 provided in the tub 20, and the bottom surfaces 33 of the plurality of electrodes 32 may be immersed in the electrolyte 11 and may face and be spaced apart from the substrate 12 at a predetermined interval by movement of the multi-electrode module 30 due to an operation of the driver 13.

When the substrate 12 and the bottom surfaces 33 of the plurality of electrodes 32 are immersed in the electrolyte 11 accommodated in the tub 20 while facing each other with a predetermined interval therebetween, the controller 14 may control the power supply 50 to apply power to the substrate 12 and the plurality of electrodes 32 by using the plurality of electrodes 32 as (+) and the substrate 12 as (−), the metal ions included in the electrolyte 11 may be electrochemically deposited on an area 17 of the substrate 12, in which the bottom surfaces 33 of the electrodes 32 face each other, and thus may be stacked.

Therefore, the controller 14 may control the driver 13 and the power supply 50 to selectively electrochemical-deposit and stack metal ions contained in the electrolyte 11 on the substrate 12.

The driver 13 may be configured to control the movement of the multi-electrode module 30 and provided to drive the multi-electrode module 30 in horizontal and vertical directions.

For example, the driver 13 may horizontally move the multi-electrode module 30 to select a position of the substrate 12, at which the multi-electrode module 30 is to be stacked, and after a predetermined height of stacking is completed, for example, after a preset 1-layer stacking is completed, the multi-electrode module 30 may be moved vertically by approximately the height of the 1-layer stacking to adjust a gap between the substrate 12 and the bottom surfaces 33 of the plurality of electrodes 32.

That is, the driver 13 may drive the multi-electrode module 30 to control the three-dimensional displacement including the gap between the bottom surfaces 33 of the plurality of electrodes 32 and the substrate 12.

Conventionally, a method using a mask is mainly used as a method for forming a bonding layer for mounting chips on a semiconductor circuit board, but this method has problems such as high equipment cost and investment cost, long process time, and increased environmental costs due to an exposure process and a strip process for removing photoresist.

### DISCLOSURE

### Technical Problem

The present disclosure provides a selective electrochemical additive manufacturing (S-ECAM) printing device for selectively stacking a metal raw material on a substrate by using electrochemical additive manufacturing (ECAM).

The present disclosure provides an S-ECAM printing device for forming a bonding layer for mounting a chip on a circuit board without using a mask.

### Technical Solution

According to an embodiment of the present disclosure, a selective electrochemical additive manufacturing (S-ECAM) printing device includes a bath, a substrate support provided in the bath and having a substrate located on the substrate support, an electrode module including an electrode holder having an inlet through which electrolyte is introduced and an outlet through which the electrolyte introduced through the inlet is discharged, a plurality of electrodes provided at predetermined intervals on a bottom surface of the electrode holder, and a cover coupled to an upper portion of the electrode holder, a power supply configured to supply power by using the electrode as an anode and the substrate as a cathode, a storage unit storing electrolyte, a pump supplying the electrolyte stored in the storage unit to the inlet, and a controller configured to apply power to the power supply to electrochemically deposit metal ions included in the electrolyte on a predetermined area of the substrate, which faces the electrode, in a state in which the electrode and the substrate are immersed in the electrolyte discharged from the outlet of the electrode holder while being spaced apart from each other by a predetermined interval, wherein an anode plate connected to an anode of the power supply and a cathode plate connected to a cathode of the power supply are fixed to the cover, and the electrode holder includes an anode probe connecting the electrode and the anode plate to each other, and a cathode probe connecting the substrate and the cathode plate to each other.

According to an embodiment of the present disclosure, an electrode module includes an electrode holder having an inlet through which electrolyte is introduced and an outlet through which the electrolyte introduced through the inlet is discharged, a plurality of electrodes provided at predetermined intervals on a bottom surface of the electrode holder, a cover coupled to an upper portion of the electrode holder, an anode plate fixed to the cover, and a cathode plate fixed to the cover, wherein the electrode holder includes an anode probe connecting the electrode and the anode plate to each other, and a cathode probe connected to the anode plate and protruding below the electrode holder.

### Advantageous Effects

When a selective electrochemical additive manufacturing (S-ECAM) printing device according to an embodiment of the present disclosure is used, a bonding layer for mounting a chip on a circuit board may be formed without using a mask by using electrochemical additive manufacturing (ECAM), and thus an exposure process and a strip process of removing photoresist, which are required when a mask is used, are not required, thereby obtaining an effect such as lower equipment price and investment cost, shortened process time, and minimized environmental costs.

It will be appreciated by those of skill in the art that that the effects that could be achieved with the present disclosure are not limited to what has been particularly described hereinabove and other advantages of the present disclosure will be more clearly understood from the following claims and detailed description.

### BRIEF DESCRIPTION OF THE DRAWINGS

FIG. 1 is a diagram showing a conventional 3D printing device using selective electrochemical deposition,

FIG. 2 is a diagram showing a state in which power is applied to a substrate and an electrode,

FIG. 3 is a perspective view of a selective electrochemical additive manufacturing (S-ECAM) printing device according to an embodiment of the present disclosure,

FIG. 4 is a bottom view of an S-ECAM printing device according to an embodiment of the present disclosure,

FIG. 5 is a top perspective view of an S-ECAM printing device according to an embodiment of the present disclosure,

FIG. 6 is a schematic front view of FIG. 5,

FIG. 7 is a diagram showing a camera module according to an embodiment of the present disclosure,

FIG. 8 is a perspective view showing a bath and a pressurizer according to an embodiment of the present disclosure,

FIG. 9 is a perspective view showing a state in which a pressurizer pressurizes a substrate,

FIG. 10 is a perspective view of a bath and a substrate support according to an embodiment of the present disclosure,

FIG. 11 is a plan view of FIG. 10,

FIG. 12 is a cross-sectional view taken along line A-A of FIG. 11,

FIG. 13 is a partial cross-sectional view of a substrate support according to another embodiment of the present disclosure,

FIG. 14 is a perspective view of an electrode module according to an embodiment of the present disclosure,

FIG. 15 is an exploded perspective view of an electrode module according to an embodiment of the present disclosure,

FIG. 16 is a vertical cross-sectional view of an electrode module according to an embodiment of the present disclosure,

FIG. 17 is a bottom view of a cover according to an embodiment of the present disclosure,

FIG. 18 is diagram showing a bottom surface of an electrode module according to an embodiment of the present disclosure,

FIG. 19 is a schematic side view of an S-ECAM printing device according to an embodiment of the present disclosure,

FIG. 20 is a schematic front view of FIG. 19,

FIG. 21 is a combined perspective view of a cleaning block according to an embodiment of the present disclosure,

FIG. 22 is an exploded perspective view of the cleaning block shown in FIG. 21,

FIG. 23 is a schematic side view of an S-ECAM printing device according to an embodiment of the present disclosure,

FIG. 24 is a schematic perspective view showing a state in which a partition frame is located behind a bath,

FIG. 25 is a schematic perspective view showing a state in which a partition frame is located above a substrate support,

FIG. 26 is a schematic vertical cross-sectional view showing a fifth driver according to another embodiment of the present disclosure,

FIG. 27 is a schematic vertical cross-sectional view showing an S-ECAM printing device according to an embodiment of the present disclosure, and

FIG. 28 is a diagram showing a method of controlling an S-ECAM printing device according to an embodiment of the present disclosure.

### DETAILED DESCRIPTION

Hereinafter, an embodiment is described in detail with reference to the attached drawings. In the description of the drawings, the same elements are denoted by the same reference numerals, and a repeated explanation thereof will not be given.

The terms such as “first” and “second” are used herein merely to describe a variety of constituent elements, but the constituent elements are not limited by the terms, and the terms are used only for the purpose of distinguishing one constituent element from another constituent element.

When a certain part “comprises (includes)” a certain component, this indicates that the part may further include another component instead of excluding another component unless there is no different disclosure.

The thickness or size of each layer (film), area, pattern or structure in the drawing may be modified for clarity and convenience of explanation, and therefore does not entirely reflect the actual size. In the description of the embodiments, when each layer (membrane), area, pattern or structure is stated as being “over”, “on” or “under” of a substrate, each layer (film), area, pad or pattern, this means that each layer (membrane), area, pattern or structure is directly on another substrate, each layer (film), area, pad or pattern or is indirectly on another substrate, each layer (film), area, pad or pattern by intervening layers.

The “on” means located above or below a target object, and does not necessarily mean located above in a direction of gravity.

In this specification, relative terms such as ‘upper’, ‘lower surface’, ‘top surface’, ‘bottom surface’, ‘upward’, and ‘downward’ may be used to describe a relationship between components based on a direction illustrated in the drawings, and the present disclosure is not limited by such terms.

Embodiments may be implemented independently or together, and some components may be excluded to comfort to the object of the disclosure.

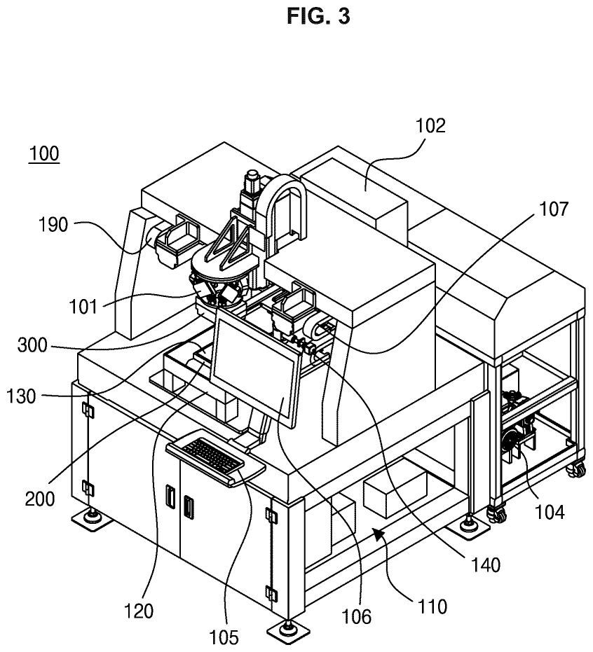

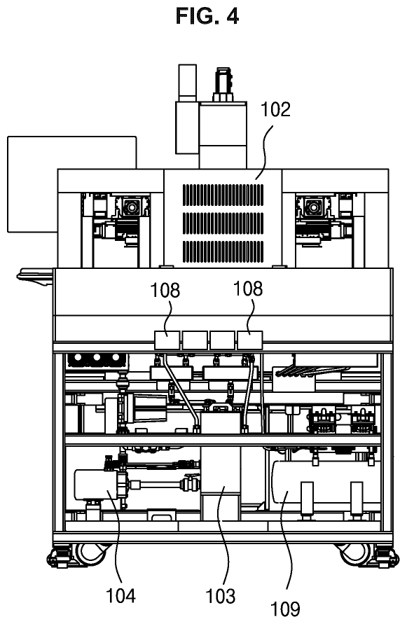

FIG. 3 is a perspective view of a selective electrochemical additive manufacturing (S-ECAM) printing device according to an embodiment of the present disclosure, and FIG. 4 is a rear view of an S-ECAM printing device according to an embodiment of the present disclosure.

Referring to FIGS. 3 and 4, an S-ECAM printing device 100 according to an embodiment of the present disclosure may include a bath 120, a substrate support 200 provided in the bath 120 and having a substrate 130 placed thereon, and an electrode module 300 located at a predetermined distance above the substrate support 200.

The substrate 130 may be a circuit board. For example, the S-ECAM printing device 100 according to the present disclosure may be used to form a bonding layer for mounting a chip on the circuit board.

The electrode module 300 may include an electrode holder having an inlet for introducing electrolyte and an outlet for discharging the electrolyte introduced through the inlet, and a plurality of electrodes provided at predetermined intervals on bottom surfaces of the electrode holder. A detailed explanation thereof will be given later.

The S-ECAM printing device 100 according to an embodiment of the present disclosure may include a first driver 101 that moves the electrode module 300, a power supply 102 that applies power by using an electrode formed on the bottom surface of the electrode holder as an anode and the substrate 130 as a cathode, a storage unit 103 in which electrolyte is stored, and a pump 104 that supplies the electrolyte stored in the storage unit 103 to the inlet of the electrode holder.

The S-ECAM printing device 100 according to an embodiment of the present disclosure may include a controller 110 that controls the first driver 101, the power supply 102, and the pump 104.

Therefore, when power is applied to the power supply 102 while the electrode and the substrate 130 are spaced apart from each other by a predetermined distance and are immersed in the electrolyte discharged from the outlet of the electrode holder, the metal ions included in the electrolyte may be electrochemically deposited on a predetermined area of the substrate 130, which faces the electrode.

For example, the controller 110 may control an operation of the first driver 101 such that the electrode and the substrate 130 are spaced apart by a predetermined distance, control an operation of the pump 104 such that the electrode and the substrate 130 may be immersed in the electrolyte while the electrode and the substrate 130 are spaced apart by the predetermined distance, and control an operation of the power supply 102 such that power may be applied to the electrode and the substrate 130 while the electrode and the substrate 130 are immersed in the electrolyte discharged from the outlet of the electrode holder. Then, printing may be performed by electrochemically depositing metal ions included in the electrolyte onto a predetermined area of the substrate 130, which faces the electrode.

The bath 120 has a space for accommodating the electrolyte discharged from the outlet of the electrode holder, and the bath 120 may include an outlet for discharging the accommodated electrolyte to the storage unit 103. Then, the electrolyte collected in the storage unit 103 may be supplied again to the inlet of the electrode holder by the operation of the pump 104, and thus may circulate.

The S-ECAM printing device 100 according to an embodiment of the present disclosure may include an input unit 105 for inputting printing conditions, such as electrolyte conditions such as pressure and flow rate, gap conditions between the substrate 130 and the electrode, power supply conditions such as constant current and constant voltage, and a display 106 that displays a user interface (UI) that allows a user to input the conditions and a state in which electrochemical deposition is performed on a substrate.

The S-ECAM printing device 100 according to an embodiment of the present disclosure may include a camera module 140 equipped with a camera that detects a substrate alignment mark formed on the substrate 130 and an electrode alignment mark formed on the electrode holder, and a second driver 107 that moves the camera module 140, and the controller 110 may control an operation of the second driver 107.

Then, the controller 110 may control the first driver 101 and the second driver 107 such that the substrate alignment mark and the electrode alignment mark that are detected in the camera overlap each other to align the substrate 130 and the electrode module with each other. A detailed explanation thereof will be given later.

The S-ECAM printing device 100 according to an embodiment of the present disclosure may include a vacuum pump 108 that fixes a substrate placed on the substrate support 200 through a vacuum hole formed in the substrate support 200, and an air compressor 109 that generates pneumatic pressure, and the controller 110 may control operations of the vacuum pump 108 and the air compressor 109.

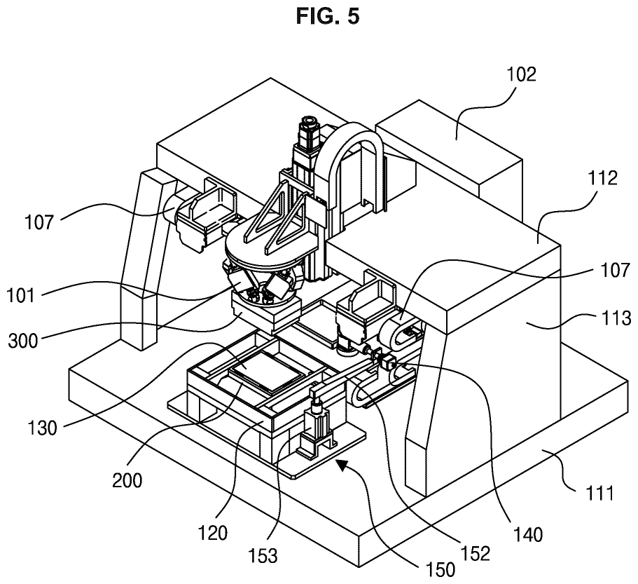

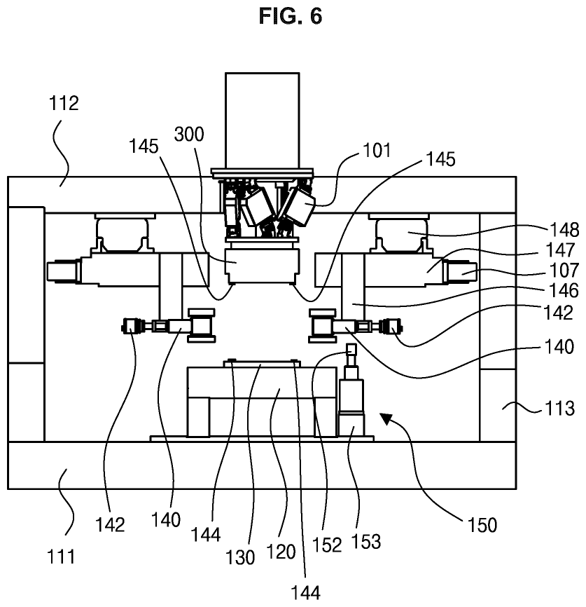

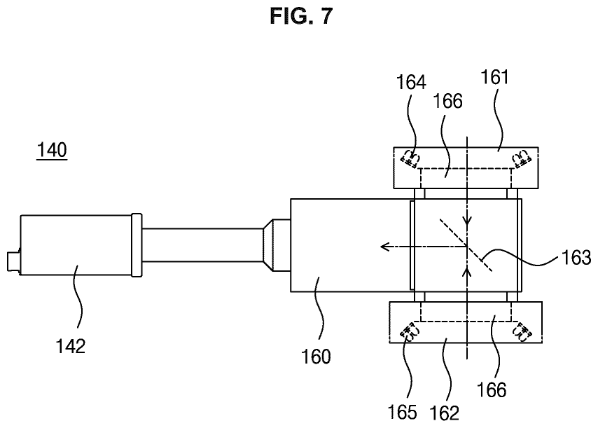

FIG. 5 is a top perspective view of an S-ECAM printing device according to an embodiment of the present disclosure, FIG. 6 is a schematic front view of FIG. 5, and FIG. 7 is a diagram showing a camera module according to an embodiment of the present disclosure.

An upper portion of the S-ECAM printing device 100 according to an embodiment of the present disclosure may be a space in which metal ions included in the electrolyte are electrochemically deposited on a substrate 120, that is, printing is performed, and may include a base frame 111, an upper frame 112, and a support frame 113 provided at an edge of the base frame 111 to support the upper frame 112.

Referring to FIGS. 5 and 6, the bath 120 may be fixed to an upper portion of the base frame 111, and the first driver 101 may be fixed to the upper frame 112.

The S-ECAM printing device 100 according to an embodiment of the present disclosure may include a pressurizer 150 located at one side of the bath 120 to pressurize the substrate 130 placed above the substrate support 200.

In this case, the controller 110 may operate the vacuum pump 108 to fix the substrate 130 while the substrate 130 is pressurized by the pressurizer 150. A detailed explanation thereof will be given later.

A substrate alignment mark 144 may be formed on an upper surface of the substrate 130, and an electrode alignment mark 145 corresponding to the substrate alignment mark 144 may be formed on a bottom surface of the electrode module 300.

The substrate alignment mark 144 and the electrode alignment mark 145 are for alignment of the substrate 130 and the electrode module 300.

The camera module 140 may include a camera 142 that detects the substrate alignment mark 144 and the electrode alignment mark 145.

The second driver 107 may be provided to enable left-right and forward-backward driving, and the camera module 140 may be provided to enable left-right and forward-backward movement according to driving of the second driver 107.

For example, the S-ECAM printing device 100 according to an embodiment of the present disclosure may include a support 146 that supports the camera module 140, a left and right guide 147 that guides left and right movement of the support 146, and a front and rear guide 148 that is fixed to the upper frame 112 and guides front and rear movement of the first guide 147.

Then, the camera module 140 may move left and right, and forward and backward according to driving of the second driver 107.

Referring to FIG. 7, the camera module 140 according to an embodiment of the present disclosure may include a body 160 including the camera 142 provided at one side, an upper opening 161 provided above the other side of the body 160, and a lower opening 162 provided below the other side of the body 160.

A beam splitter 163 that reflects light incident on the upper opening 161 and light incident on the lower opening 162 toward the camera 142 and an optical system that allows light reflected from the beam splitter 163 to be incident on the camera 142 may be provided inside the body 160.

An upper lighting unit 164 may be provided in the upper opening 161, a lower lighting unit 165 may be provided in the lower opening 162, and a lens 166 may be provided in each of the upper opening 161 and the lower opening 162.

The controller 110 may control the on/off of the upper lighting unit 164 and the lower lighting unit 165.

The controller 110 may control the first driver 101 and the second driver 107 such that the substrate alignment mark 144 and the electrode alignment mark 145 that are detected in the camera 142 overlap each other to align the substrate 130 and the electrode module with each other.

For example, the controller 110 may control the second driver 107 such that the camera 142 detects the substrate alignment mark 144, then control the first driver 101 such that the camera 142 detects the electrode alignment mark 145, and then control the first driver 101 such that the substrate alignment mark 144 and the electrode alignment mark recognized by the camera 142 overlap each other, thereby aligning the substrate 130 and the electrode module 300 with each other.

In this case, the controller 110 may turn on the lower lighting unit 165 and turn off the upper lighting unit 164 when the camera 142 detects the substrate alignment mark 144, and may turn off the lower lighting unit 165 and turn on the upper lighting unit 164 when the camera 142 detects the electrode alignment mark 145.

Then, when the substrate alignment mark 144 is detected, light noise coming from the upper lighting unit 164 may be reduced, and conversely, when the electrode alignment mark 145 is detected, light noise coming from the lower lighting unit 165 may be reduced, and accordingly, the camera 142 may easily detect the substrate alignment mark 144 and the electrode alignment mark 145.

As shown in FIG. 6, at least two substrate alignment marks 144 may be formed, and at least two electrode alignment marks 145 may be formed to correspond to the substrate alignment marks 144.

In this case, two or more camera modules 140 may be provided to simultaneously detect two or more substrate alignment marks 144 and electrode alignment marks 145.

Then, the substrate 130 and the electrode module 300 may be aligned more precisely.

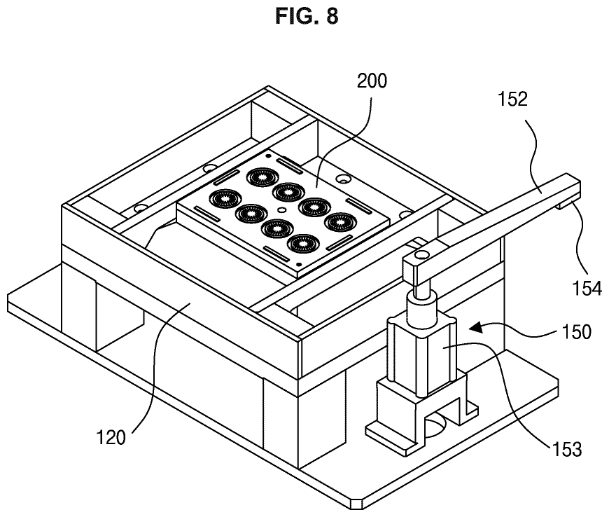

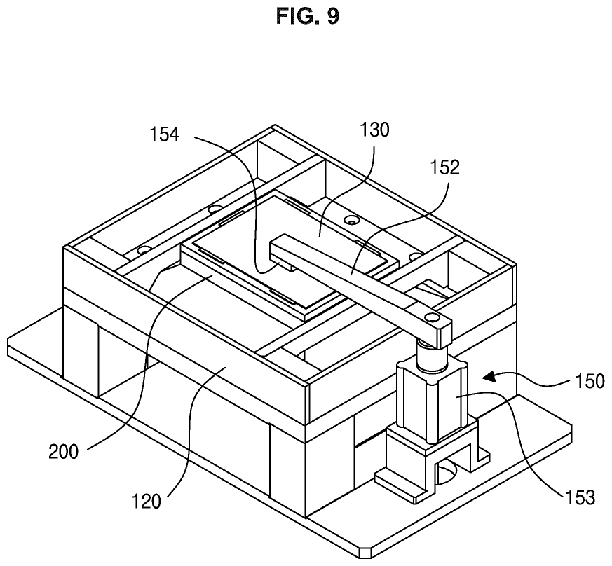

FIG. 8 is a perspective view showing a bath and a pressurizer according to an embodiment of the present disclosure, and FIG. 9 is a perspective view showing a state in which a pressurizer pressurizes a substrate.

Referring to FIGS. 8 and 9, the pressurizer 150 according to an embodiment of the present disclosure may include a rod 152 provided at one side of the bath 120, and a third driver 153 that rotates the rod 152 to pressurize the substrate 130.

The controller 110 may control an operation of the third driver 153 to pressurize the substrate 130 placed above the substrate support 200.

The controller 110 may operate the third driver 153 and operate the vacuum pump 108 while the substrate 130 is pressurized by the pressurizer 150 to fix the substrate 130.

Then, the substrate 130 may be fixed in a flat state. When the substrate 130 is placed on the substrate support 200, a central portion of the substrate 130 is lifted, and in the present embodiment, the substrate 130 in the lifted state is pressurized to make it flat, and in this regard, to fix the substrate 130 flattened by the pressurization in the state, the vacuum pump 108 is operated while the substrate 130 is pressurized.

The third driver 153 according to an embodiment of the present disclosure may include a rotation driver that rotates the rod 152 above the substrate 130, and a vertical driver that lowers the rod 152 rotated above the substrate 130 to pressurize the substrate 130.

According to another embodiment, the third driver 153 may use a rotary actuator that rotates and lowers the rod 152. The rotary actuator may be operated by pneumatic pressure from the air compressor 109.

The rotary actuator may be a cylinder that rotates and reciprocates within a set angular range and has an output shaft, and by utilizing the rotary actuator, rotation and vertical movement may be simultaneously performed with a single configuration, thereby simplifying the configuration of the third driver 153.

A damage prevention member 154 may be provided at a lower end of an end of the rod 152 to prevent damage to the substrate 130 when the rod 152 pressurizes the substrate 130. For example, a rubber pad may be used as the damage prevention member 154.

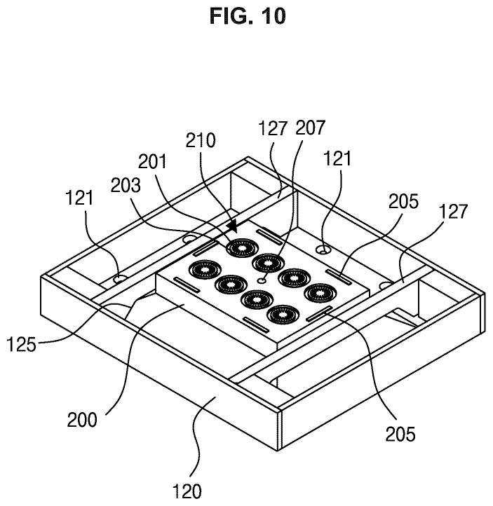

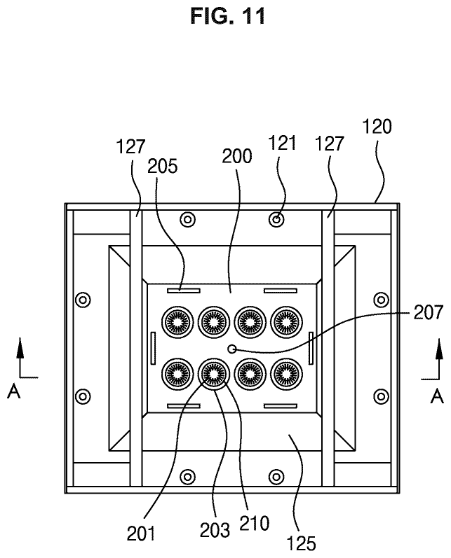

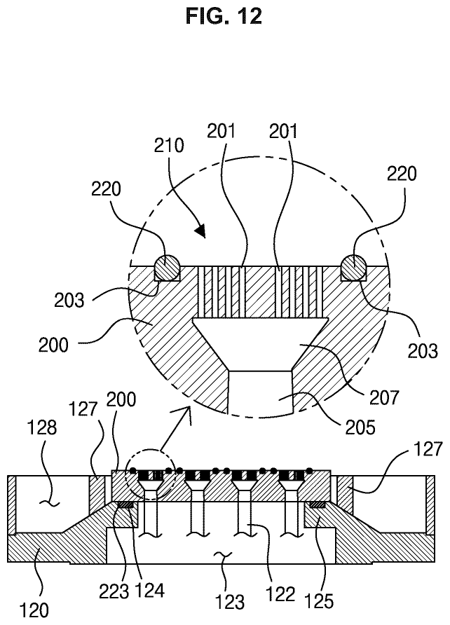

FIG. 10 is a perspective view of a bath and a substrate support according to an embodiment of the present disclosure, FIG. 11 is a plan view of FIG. 10, and FIG. 12 is a cross-sectional view taken along line A-A of FIG. 11, showing a state in which a first sealing member is provided.

Referring to FIGS. 10 to 12, a vacuum hole 201 connected to the vacuum pump 108 may be formed in the substrate support 200 according to an embodiment of the present disclosure.

A first sealing member 220 may be provided on an upper surface of the substrate support 200 to prevent electrolyte from flowing into the vacuum hole 201.

For example, the first sealing member 220 may be provided to surround the vacuum hole 201 at a predetermined interval.

Then, when the substrate 130 is pushed downward, i.e., toward the upper surface of the substrate support 200, by the vacuum pump 108, the substrate 130 may pressurize the first sealing member 220, thereby preventing the electrolyte from flowing into the vacuum hole 201.

As such, in a state in which the substrate 130 pressurizes the first sealing member 220 to prevent the electrolyte from flowing into the vacuum hole 201, the controller 110 may operate the pump 104 to supply the electrolyte stored in the storage unit 103 to the inlet of the electrode module 300.

Insertion grooves 203 may be formed at a predetermined interval in the upper surface of the substrate support 200 to surround the vacuum hole 201, and the first sealing member 220 may be provided to surround the vacuum hole 201 by being inserted into the insertion groove 203.

The vacuum hole forming area 210 in which a plurality of vacuum holes 201 are formed may be formed on the upper surface of the substrate support 200, and the first sealing member 220 may be provided to surround the vacuum hole forming area 210.

For example, insertion grooves 203 may be formed at a predetermined interval in the upper surface of the substrate support 200 to surround the vacuum hole forming area 210, and the first sealing member 220 may be provided to surround the vacuum hole forming area 210 by being inserted into the insertion groove 203.

A plurality of vacuum hole forming areas 210 may be formed at predetermined intervals on the upper surface of the substrate support 200. Then, the substrate 130 located on the substrate support 200 may be evenly and firmly fixed. In this case, the number of the first sealing members 220 may be provided equal to the number of the vacuum hole forming areas 210.

A coupling hole 205 to which a connecting pipe 122 connected to the vacuum pump 108 may be formed in a lower portion of the substrate support 200, and a connecting hole 207 may be formed between the coupling hole 205 and the vacuum hole 201 to communicate with each other.

When the vacuum hole forming area 210 is formed on a surface of the substrate support 200, one coupling hole 205 may be formed at a lower portion of the vacuum hole forming area 210, and in this case, an upper cross-sectional size of the connecting hole 207 may have a size that includes all of the plurality of vacuum holes 201 formed in the vacuum hole forming area 210. For example, the connecting hole 207 may have a tapered shape with a cross-section that is widened upward. Then, vacuum pressure may be generated in the plurality of vacuum holes 210 formed in the vacuum hole forming area 210 with only one connecting pipe 122.

A through hole 123 through which the connecting pipe 122 passes may be formed at a lower portion of the bath 120, the substrate support 200 may be provided above the through hole 123, and a second sealing member 223 may be provided at a lower edge of the substrate support 200 to prevent electrolyte from flowing into the through hole 123.

For example, a protrusion 125 protruding upward and supporting the substrate support 200 may be formed inside the bath 120, and the through hole 123 may be formed at a lower portion of the protrusion 125.

In this case, a space 128 for accommodating electrolyte may be formed around the protrusion 125, the second sealing member 223 may be provided at an upper edge of the protrusion 125, and an insertion groove 124 into which the second sealing member 223 is inserted may be formed on at least one of a lower edge of the substrate support 200 and the upper edge of the protrusion 125.

The bath 120 may include an outlet 121 to discharge the electrolyte collected in the space 128 to the storage unit 103.

The bath 120 may include a pair of support walls 127 on both sides with the substrate support 200 therebetween to support forward and backward movement of a cleaning member to be described later. A detailed explanation thereof will be given later.

The S-ECAM printing device 100 according to the present disclosure may be used to print metal ions included in electrolyte on a circuit board. For example, the S-ECAM printing device 100 according to the present disclosure may be used to form a bonding layer for mounting a chip on the circuit board without a mask. Therefore, it is necessary to prevent damage to the substrate 130 due to pressurization.

To this end, a proximity sensor 207 for detecting the substrate 130 located there above may be provided on the upper surface of the substrate support 200, and a flange 205 by which an edge of the substrate 130 is caught to guide a correct position of the substrate 130 may be formed at the edge of the upper surface of the substrate support 200.

Then, the controller 110 may determine whether the substrate 130 is positioned at the correct position of the upper portion of the substrate support 200 depending on whether the proximity sensor 207 detects the substrate 130.

When the substrate 130 is not positioned inside the flange 205 of the upper surface of the substrate support 200 and a portion of the edge of the substrate 130 hangs over the flange 205, the substrate 130 is lifted by a predetermined distance from the upper surface of the substrate support 200, and thus the proximity sensor 207 may not detect the substrate 130.

Conversely, when the substrate 130 is located inside the flange 205, the substrate 130 is not lifted from the upper surface of the substrate support 200, and thus the proximity sensor 207 may detect the substrate 130.

That is, the controller 110 may determine whether the substrate 130 is located inside the flange 205, that is, whether the substrate 130 is located at the correct position of the upper portion of the substrate support 200, depending on whether the proximity sensor 207 detects the substrate 130.

Therefore, when the proximity sensor 207 detects the substrate 130, the controller 110 may control an operation of the pressurizer 150, for example, the third driver 153 such that the pressurizer 150 pressurizes the substrate 130, thereby guiding the substrate 130 to be positioned at the correct position of the upper portion of the substrate support 200 and also preventing damage to the substrate 130 due to pressurization.

When the substrate 130 is not detected by the proximity sensor 207, the controller 110 may determine that the substrate 130 is not located inside the flange 205 but partially hangs over the flange 205 and generate a warning sound or warning light to inform an operator that the substrate 130 is not located at the correct position.

The controller 110 may operate the vacuum pump 108 to fix the substrate 130 while the substrate 130 is pressurized by the pressurizer 150.

In this case, the controller 110 may determine whether the substrate 130 is firmly fixed or whether the inside of the vacuum hole 201 is completely sealed by measuring the pressure inside the vacuum hole 201.

When the pressure inside the vacuum hole 201 is equal to or less than a reference value, the controller 110 may determine that the inside of the vacuum hole 201 is not completely sealed and that the substrate 130 is not firmly fixed, and stop all operations and generate a warning sound or warning light to notify the operator.

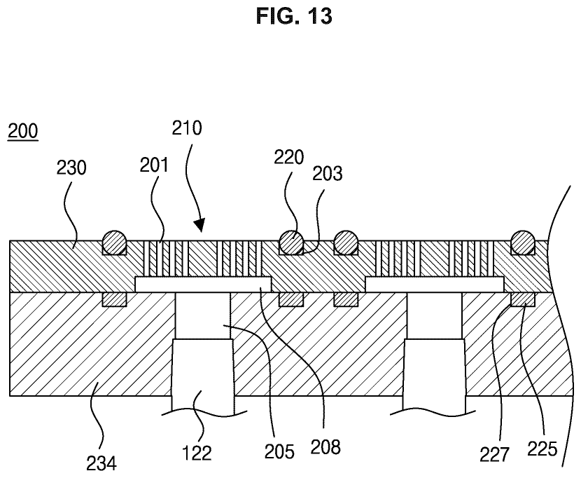

FIG. 13 is a partial cross-sectional view of a substrate support according to another embodiment of the present disclosure.

Referring to FIG. 13, the substrate support 200 according to the present embodiment may include an upper plate 230 defining the upper surface of the substrate support 200, and a lower plate 234 coupled to a lower portion of the upper plate 230.

The vacuum hole forming area 210 in which the plurality of vacuum holes 201 are formed may be formed on the upper surface of the upper plate 230, and the first sealing member 220 may be provided to surround the vacuum hole forming area 210.

The coupling hole 205 to which the connecting pipe 122 connected to the vacuum pump 108 is coupled may be formed at a lower portion of the lower plate 234.

A connecting groove 208 may be formed at a lower portion of the upper plate 230 to connect the coupling hole 205 and the plurality of vacuum holes 201 formed in the vacuum hole forming area 210, and an upper cross-sectional size of the connecting groove 208 may have a size that includes all of the plurality of vacuum holes 201 formed in the vacuum hole forming area 210. Then, vacuum pressure may be generated in the plurality of vacuum holes 210 formed in the vacuum hole forming area 210 with only one connecting pipe 122.

The through hole 123 through which the connecting pipe 122 passes may be formed at the lower portion of the bath 120, the lower plate 234 may be provided above the through hole 123, and the second sealing member 223 may be provided at a lower edge of the lower plate 234 to prevent electrolyte from flowing into the through hole 123.

A third sealing member 225 surrounding the connecting groove 208 may be provided between the upper plate 230 and the lower plate 234 to prevent electrolyte from flowing into the connecting groove 208. In this case, an insertion groove 227 into which the third sealing member 225 is inserted may be formed in at least one of the upper plate 230 and the lower plate 234.

To manufacture the substrate support 200, the vacuum hole 201 and the coupling hole 205 having different sizes may be formed on the upper and lower portions of a single plate, respectively, but as in the substrate support 200 according to the present embodiment, the substrate support 200 may be easily manufactured by separately manufacturing the upper plate 230 in which the plurality of vacuum holes 201 are formed and the lower plate 234 in which the coupling hole 205 is formed and then coupling the upper plate 230 and the lower plate 234.

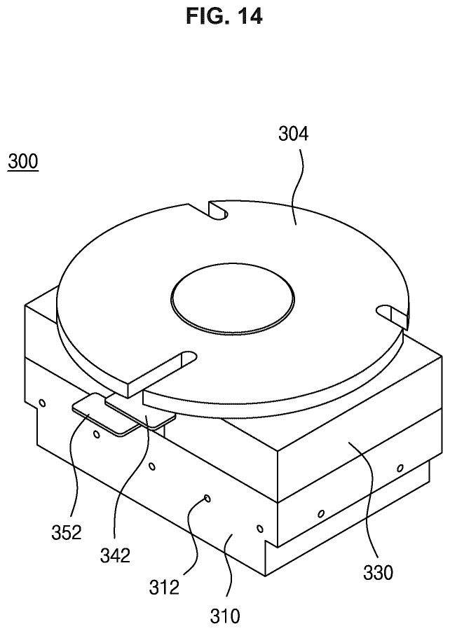

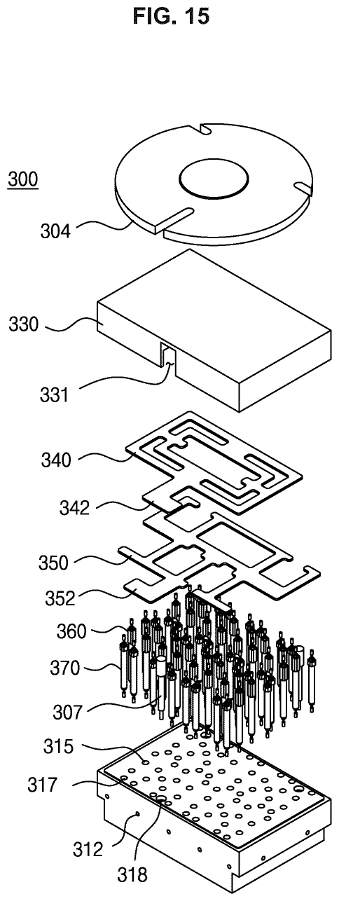

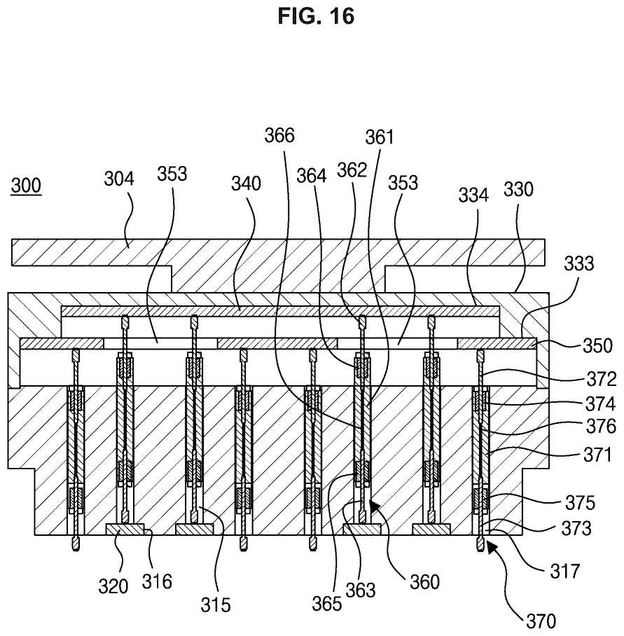

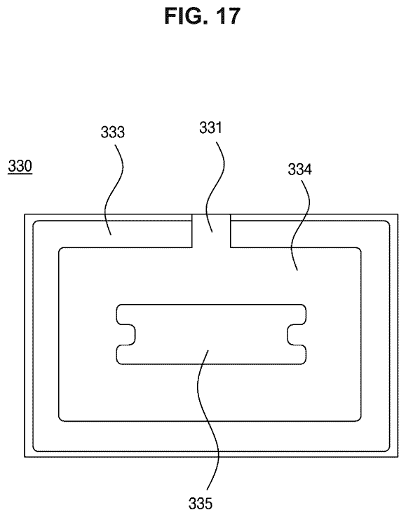

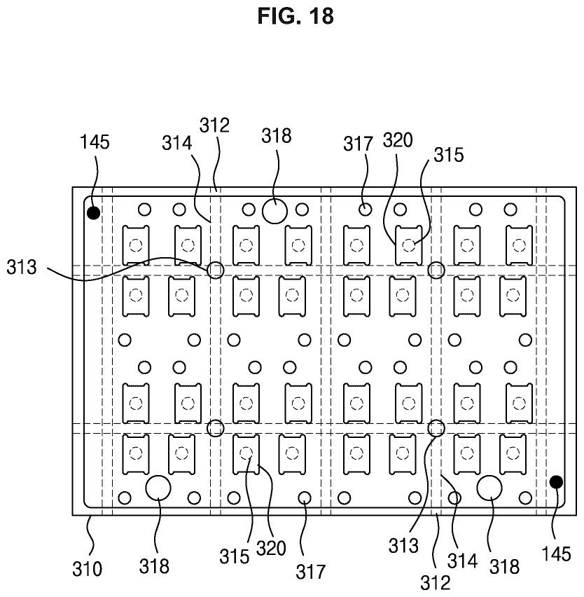

FIG. 14 is a perspective view of an electrode module according to an embodiment of the present disclosure, FIG. 15 is an exploded perspective view of an electrode module according to an embodiment of the present disclosure, FIG. 16 is a vertical cross-sectional view of an electrode module according to an embodiment of the present disclosure, FIG. 17 is a bottom view of a cover according to an embodiment of the present disclosure, and FIG. 18 is diagram showing a bottom surface of an electrode module according to an embodiment of the present disclosure.

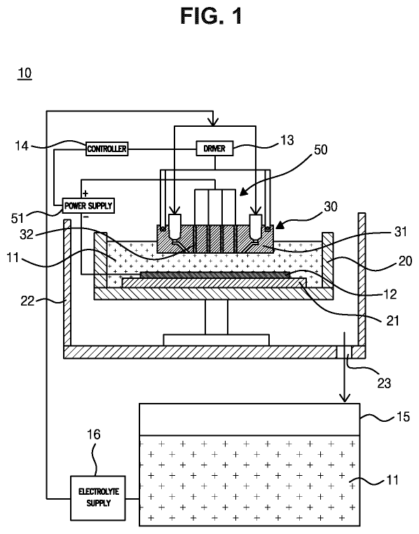

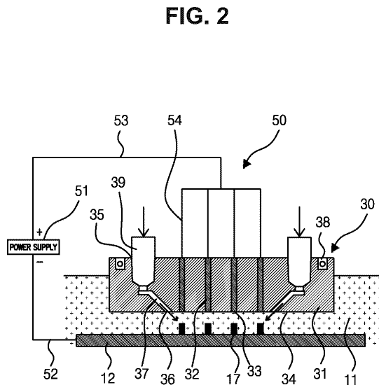

In the conventional 3D printing device 10 using selective electrochemical deposition (see FIGS. 1 and 2), an electrode 32 is electrically connected to the power supply 50 through the multi-electrode module 30, and the substrate 12 is electrically connected directly to the power supply 50, but there are many difficulties in directly connecting the substrate 12 to the power supply 50 due to space constraints.

In particular, the S-ECAM printing device 100 according to an embodiment of the present disclosure may be used to form a bonding layer for mounting a chip on a semiconductor circuit board, and in this case, the substrate is a semiconductor circuit board, and the electrode is an area on the semiconductor circuit board, in which the bonding layer is to be formed, and accordingly, to print on the area, the electrode needs to be electrically connected to the surrounding area of the area, but there are several areas on the substrate that are not electrically connected to each other, and thus it is very difficult to electrically connect the substrate directly to the power supply.

To resolve the above problem, an electrode module according to an embodiment of the present disclosure may be configured such that not only the electrode but also the substrate is electrically connected to the power supply.

Referring to FIGS. 14 to 18, the electrode module 300 according to an embodiment of the present disclosure may include an electrode holder 310 having an inlet 312 for introducing electrolyte and an outlet 313 for discharging electrolyte introduced through the inlet 312, a plurality of electrodes 320 provided at predetermined intervals on a bottom surface of the electrode holder 310, a cover 330 coupled to the upper portion of the electrode holder 310) an anode plate 340 fixed to the cover 330, and a cathode plate 350 fixed to the cover 330.

The anode plate 340 may be connected to an anode of the power supply unit 102, and the cathode plate 350 may be connected to the cathode of the power supply 102.

For example, the anode plate 340 may include an anode connector 342 connected to the anode of the power supply 102, the cathode plate 350 may include a cathode connector 352 connected to the cathode of the power supply 102, and the cover 330 may include a power connection groove 331 that allows the anode connector 342 and the cathode connector 352 to protrude outside the cover 330.

The electrode holder 310 may include an anode probe 360 that connects the electrode 320 and the anode plate 340, and a cathode probe 370 that connects the substrate 130 and the cathode plate 350.

An upper end of the cathode probe 370 may be connected to the cathode plate 350, a lower end of the cathode probe 370 may protrude below the electrode holder 310, and the protruding lower end may be connected to the substrate 130.

An anode probe hole 315 into which the anode probe 360 is inserted, a fixing groove 316 into which the electrode 320 is fixed at a lower end of the anode probe hole 315, and a cathode probe hole 317 into which the cathode probe 370 is inserted may be formed in the electrode holder 310.

The anode probe 360 may be inserted into the anode probe hole 315 such that the lower end of the anode probe 360 is in contact with the electrode 320 and the upper end of the anode probe 360 is in contact with the anode plate 340, thereby electrically connecting the electrode 320 and the anode plate 340.

The cathode probe 370 may be inserted into the cathode probe hole 317 such that the lower end of the cathode probe 370 protrudes below the electrode holder 310, the upper end of the cathode probe 370 is in contact with the cathode plate 350, and the protruding lower end is in contact with the substrate 130 to electrically connect the substrate 130 and the cathode plate 350.

Then, the electrode module 300 according to an embodiment of the present disclosure may electrically connect not only the electrode 320 but also the substrate 130 to the power supply 102.

The anode probe 360 may include an anode probe body 361, an anode upper contact portion 362 fixed to the upper end of the anode probe body 361 and in contact with the anode plate 340, and an anode lower contact portion 363 fixed to the lower end of the anode probe body 361 and in contact with the electrode 320.

The anode probe 360 may include an anode upper elastic member 364 provided between the upper end of the anode probe body 361 and the anode upper contact portion 362 to provide upward elasticity. Then, the anode upper contact portion 362 may be in stable contact with the anode plate 340 by the anode upper elastic member 364.

The anode probe 360 may include an anode lower elastic member 365 provided between the lower end of the anode probe body 361 and the anode lower contact portion 363 to provide downward elasticity. Then, the anode lower contact portion 363 may be in stable contact with the electrode 320 by the anode lower elastic member 365.

The anode upper elastic member 364 and the anode lower elastic member 365 may use springs.

The anode probe 360 may be configured to electrically connect the electrode 320 and the anode plate 340. For example, the anode probe body 361, the anode upper contact portion 362, and the anode lower contact portion 363 may include a material that conducts electricity, such as copper or a gold-plated metal material. Alternatively, the anode upper contact portion 362 and the anode lower contact portion 363 may include an electrically conductive material, such as copper or a gold-plated metal material, and the anode probe body 361 may include a wire 366 that electrically connects the anode upper contact portion 362 and the anode lower contact portion 363.

Similarly, the cathode probe 370 may include a cathode probe body 371 inserted into the cathode probe hole 317, a cathode upper contact portion 372 coupled to an upper portion of the cathode probe body 371 and in contact with the cathode plate 350, and a cathode lower contact portion 373 coupled to a lower portion of the cathode probe body 371 and protruding to the lower portion of the electrode holder 310 and in contact with the substrate 130.

The cathode probe 370 may include a cathode upper elastic member 374 provided between the upper end of the cathode probe body 371 and the cathode upper contact portion 372 to provide upward elasticity.

Then, the cathode upper contact portion 372 may be in stable contact with the cathode plate 350 by the cathode upper elastic member 374.

The cathode probe 370 may include a cathode lower elastic member 375 provided between the lower end of the cathode probe body 371 and the cathode lower contact portion 373 to provide downward elasticity. Then, the cathode lower contact portion 373 may be in stable contact with the substrate 130 by the cathode lower elastic member 375.

The cathode upper elastic member 374 and the cathode lower elastic member 375 may use springs.

The cathode probe 370 may be configured to electrically connect the substrate 130 and the cathode plate 350. For example, the cathode probe body 371, the cathode upper contact portion 372, and the cathode lower contact portion 373 may include a material that conducts electricity, such as copper or a gold-plated metal material. Alternatively, the cathode upper contact portion 372 and the cathode lower contact portion 373 may include an electrically conductive material, such as copper or a gold-plated metal material, and the cathode probe body 371 may include a wire 376 that electrically connects the cathode upper contact portion 372 and the cathode lower contact portion 373.

The anode plate 340 and the cathode plate 350 may be fixed to the cover 330 with a height difference such that the anode plate 340 and the cathode plate 350 are not in contact with each other.

For example, a step portion 333 and an accommodation groove 334 having different heights may be formed in the cover 330, and any one of the anode plate 340 and the cathode plate 350 may be fixed in a supported state on the step portion 333, and the other may be fixed in an accommodated state on the accommodation groove 334.

As shown in FIG. 17, the step portion 333 may be formed on an edge of the cover, the accommodation groove 334 may be formed inside the step portion 333, and the accommodation groove 334 may include a fixing block 335 for fixing the anode plate 340 or the cathode plate 350 to be fixed in the accommodation groove 334.

The anode plate 340 or the cathode plate 350 that is accommodated in the accommodation groove 334 may have a shape that matches a shape of the accommodation groove 334.

The anode plate 340 or the cathode plate 350 fixed in a state being supported by the step portion 333 may include a contact prevention hole.

For example, as shown in the diagram, when the cathode plate 350 is fixed in a state of being supported by the step portion 333 and the anode plate 340 is fixed in a state of being accommodated in the accommodation groove 334, a contact prevention hole 353 may be formed in the cathode plate 350 to prevent the anode probe 360 from being in contact with the cathode plate 350.

Conversely, when the anode plate 340 is fixed in a state of being supported by the step portion 333 and the cathode plate 350 is fixed in a state of being accommodated in the accommodation groove 334, a contact prevention hole may be formed in the anode plate 340 to prevent the cathode probe 370 from being in contacting with the anode plate 340.

The electrode module 300 according to an embodiment of the present disclosure may include a bracket 304 provided above the cover 330 and fixedly coupled to the first driver 101.

At least three gap sensors 307 may be provided in the electrode module 300 according to an embodiment of the present disclosure.

Then, the controller 110 may control an operation of the first driver 101 based on detection by the gap sensor 307 such that the bottom surface of the electrode module 300 is located in parallel to the upper surface of the substrate 130.

A gap sensor hole 318 into which the gap sensor 307 is inserted, and a connecting flow path 314 connecting the inlet 312 and the outlet 313 may be formed in the electrode holder 310, and at least two electrode alignment marks 145 may be formed on the bottom surface of the electrode holder 310.

The electrode 320 may use a pt sheet that is attached and fixed to the fixing groove 316, and the fixing groove 316 may be formed such that the bottom surface of the attached pt sheet is level with the bottom surface of the electrode holder 310.

The inlet 312 may be formed on a lateral surface of the electrode holder 310, and the outlet 313 may be formed on the bottom surface of the electrode holder 310.

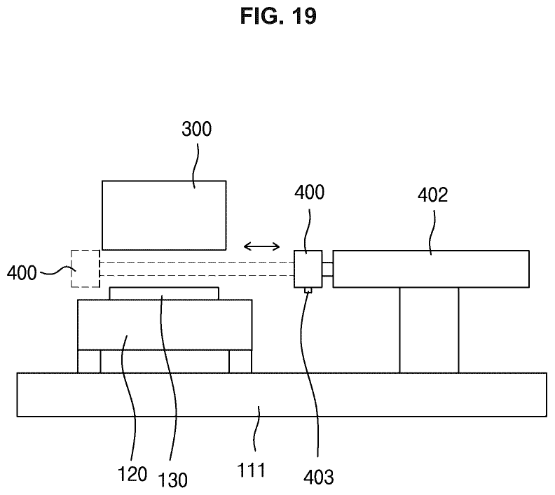

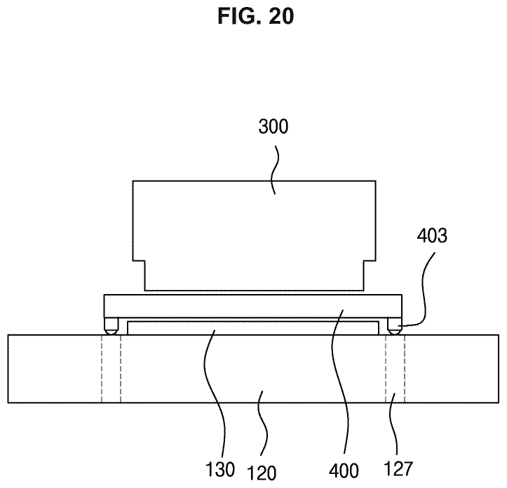

FIG. 19 is a schematic side view of an S-ECAM printing device according to an embodiment of the present disclosure, and FIG. 20 is a schematic front view of FIG. 19.

Referring to FIGS. 19 and 20, the S-ECAM printing device 100 according to an embodiment of the present disclosure may include a cleaning block 400 that cleans the substrate 130 and the electrode module 300, and a fourth driver 402 that moves the cleaning block, and the controller 110 may control an operation of the fourth driver 402 to clean the substrate 130 and the electrode module 300.

For example, the cleaning block 400 may be located behind the bath 120, and the fourth driver 402 may be configured to allow the cleaning block 400 to move forward and backward and vertically, and the controller 110 may control the operation of the fourth driver 402 such that the cleaning block 400 moves between the substrate 130 and the electrode module 300 and cleans the substrate 130 and the electrode module 300.

According to another embodiment, as shown in FIG. 19, the fourth driver 402 may include a cylinder that moves the cleaning block 400 ahead, and the cylinder may be operated by pneumatic pressure from the air compressor 109.

The cylinder may be provided at a height that enables cleaning of the upper portion of the substrate 130 when the cleaning block 400 moves horizontally forward.

Here, the height at which cleaning is possible may correspond to a height of a bottom surface of the cleaning block 400 being the same as a height of the upper surface of the substrate 130, and the height may be a height from the base frame 111.

Then, the cleaning block 400 may clean the substrate 130 and the electrode module 300 only by horizontal movement by the fourth driver 402, and thus the configuration of the fourth driver 402 may be simplified.

For example, when the controller 110 operates the fourth driver 402 after spacing the electrode module 300 away from the substrate 130 by a thickness of the cleaning block 400, the cleaning block 400 may automatically move between the substrate 130 and the electrode module 300 to clean the substrate 130 and the electrode module 300.

Generally, after a printing process is performed on the substrate 130, the substrate 130 and the electrode module 300 are left with electrolyte, and thus the cleaning block 400 may be configured to clean the electrolyte left on the substrate 130 and the electrode module 300.

For example, the cleaning block 400 may include a sponge or rubber that absorbs or removes the electrolyte remaining on the substrate 130 and the electrode module 300. Even if the cleaning block 400 includes a sponge or rubber, it is possible to clean foreign substances other than electrolyte.

A guide ball 403 may be provided at a lower portion of the cleaning block 400, and a support wall 127 that supports the guide ball 403 may be provided in the bath 120. Then, sagging of the cleaning block 400 may be prevented when the cleaning block 400 moves horizontally.

When the cleaning block 400 includes a sponge or rubber, the cleaning block 400 may be fixed to a bracket, and in this case, the guide ball 403 may be provided at the lower portion of the bracket.

According to another embodiment, the cleaning block 400 may be configured to clean the substrate 130 and the electrode module 300 by blowing or suctioning the electrolyte.

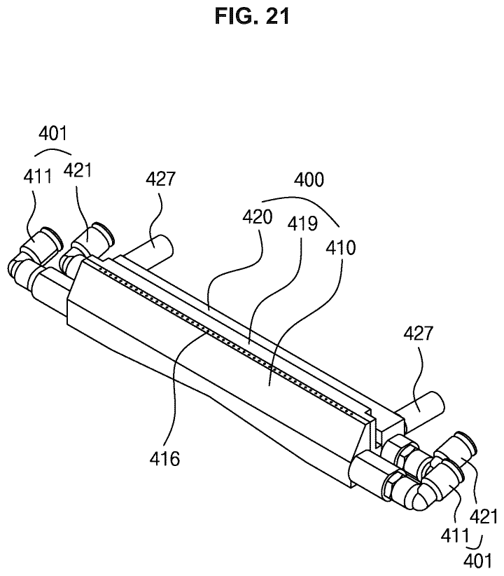

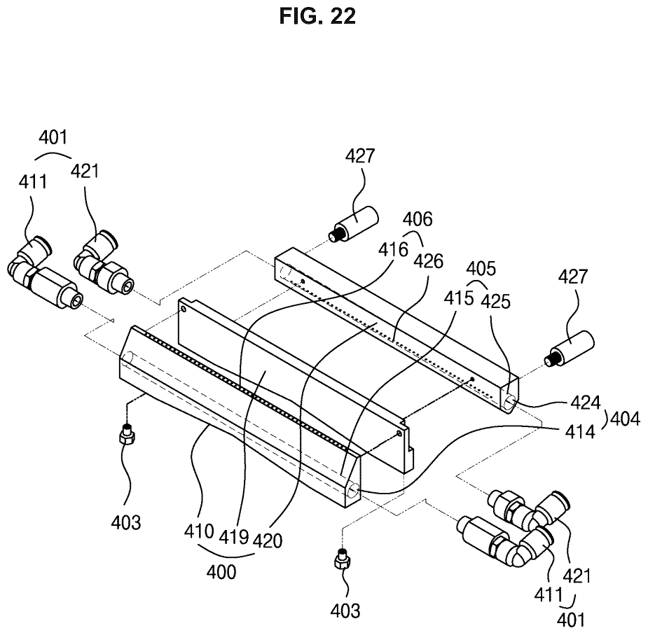

FIG. 21 is a combined perspective view of a cleaning block according to an embodiment of the present disclosure, and FIG. 22 is an exploded perspective view of the cleaning block shown in FIG. 21.

Referring to FIGS. 21 and 22, the cleaning block 400 according to the present embodiment may include a coupling hole 404 to which a connecting pipe 401 connected to the vacuum pump 108 or the air compressor 109 is connected, an internal flow path 405 connected to the coupling hole 404, and an exhaust hole 406 that connects the internal flow path 405 to the outside.

Then, the vacuum pressure of the vacuum pump 108 may be generated externally through the exhaust hole 406 to suction out foreign substances such as electrolyte stuck on the substrate 130 and the electrode module 300, or the pneumatic pressure of the air compressor 109 may be generated externally through the exhaust hole 406 to blow out foreign substances such as electrolyte stuck on the substrate 130 and the electrode module 300, and thus the substrate 130 and the electrode module 300 may be cleaned.

The coupling hole 404 may be formed on a lateral surface of the cleaning block 400, the internal flow path 405 may be formed in a long way in a longitudinal direction of the cleaning block 400 inside the cleaning block 400, and the exhaust hole 406 may be formed in multiple numbers at the upper and lower ends of the cleaning block 400.

The cleaning block 400 may be provided as a single block, but as shown in the diagram, the cleaning block 400 may include a first cleaning block 410 for cleaning the electrode module 300 and a second cleaning block 420 for cleaning the substrate 130.

A first coupling hole 414 of the first cleaning block 410 may be formed on a lateral surface of the first cleaning block 410, a first internal flow path 415 of the first cleaning block 410 may be formed in a long way in a longitudinal direction of the first cleaning block 410 inside the first cleaning block 410, and a first exhaust hole 416 of the first cleaning block 410 may be formed at an upper end of the first cleaning block 410 to clean the electrode module 300 located above the first cleaning block 410.

A second coupling hole 424 of the second cleaning block 420 may be formed on a lateral surface of the second cleaning block 420, a second internal flow path 425 of the second cleaning block 420 may be formed in a long way in a longitudinal direction of the second cleaning block 420 inside the second cleaning block 420, and a second exhaust hole 426 of the second cleaning block 420 may be formed at a lower end of the second cleaning block 420 to clean the substrate 130 located below the second cleaning block 420.

The first coupling hole 414 may be coupled to a connecting pipe connected to the vacuum pump 108 or the air compressor 109, and similarly, the second coupling hole 424 may be coupled to a connecting pipe connected to the vacuum pump 108 or the air compressor 109.

However, first exhaust hole 416 may be formed at the upper end of the first cleaning block 410, and thus when the first coupling hole 414 is coupled to a connecting pipe of the air compressor 109, a problem may occur in which the electrolyte is widely scattered due to upward blowing caused by pneumatic pressure of the air compressor 109, and therefore, as shown in the diagram, the first coupling hole 414 may be coupled to a first connecting pipe 411 connected to the vacuum pump 108 such that the electrode module 300 may be cleaned by suction caused by the vacuum pressure of the vacuum pump 108.

In this case, the second coupling hole 424 may be coupled to a second connecting pipe 421 connected to the air compressor 109. The second exhaust hole 426 may be formed at the lower end of the second cleaning block 420, and thus even if the second coupling hole 424 is coupled to the second connecting pipe 421, blowing by the pneumatic pressure of the air compressor 109 occurs downward, and thus the problem of the electrolyte scattering is relatively small, while both blowing by the pneumatic pressure of the air compressor 109 and suction by the vacuum pressure of the vacuum pump 108 may be utilized, thereby maximizing a cleaning effect.

The cleaning block 400 may include a connector block 419 disposed between the first cleaning block 410 and the second cleaning block 420 to firmly fix the first cleaning block 410 and the second cleaning block 420.

The second cleaning block 420 located behind the cleaning block 400 may include a coupler 427 coupled to the fourth driver 402.

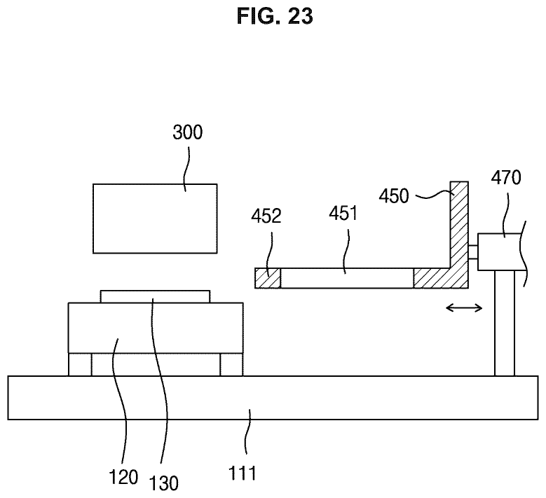

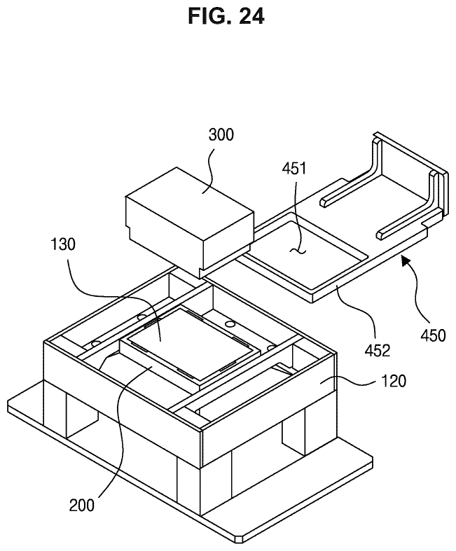

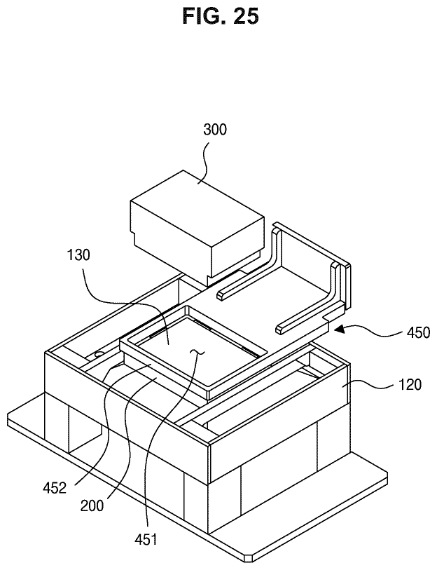

FIG. 23 is a schematic side view of an S-ECAM printing device according to an embodiment of the present disclosure, FIG. 24 is a schematic perspective view showing a state in which a partition frame is located behind a bath, and FIG. 25 is a schematic perspective view showing a state in which a partition frame is located above a substrate support.

Referring to FIGS. 23 to 25, the S-ECAM printing device 100 according to an embodiment of the present disclosure may include a partition frame 450 including a partition 452 that defines a space 451 in which the substrate 130 and the electrode 320 are immersed by the electrolyte discharged from the outlet of the electrode module 300, and a fifth driver 470 that moves the partition frame 450, and the controller 110 may control an operation of the fifth driver 470 such that the partition 452 is located above the substrate support 200.

For example, as shown in FIG. 23, the fifth driver 470 may include a cylinder that moves the partition frame 450 ahead, and the cylinder may be operated by pneumatic pressure from the air compressor 109.

In the S-ECAM printing device 100 according to an embodiment of the present disclosure, a gap between the substrate 130 and the electrode module 300 during a printing process is very small, at about 200 micrometers, and thus the substrate 130 and the electrode 320 may be immersed in the electrolyte discharged from the outlet 313 of the electrode module 300. However, as in the S-ECAM printing device 100 according to the present embodiment, a separate partition 452 may be installed above the substrate support 200 to facilitate the immersion of the substrate 130 and the electrode 320 in the electrolyte discharged from the outlet 313 of the electrode module 300.

In this case, as in the S-ECAM printing device 100 according to the present embodiment, the partition 452 may be positioned behind the bath 120 and may then move forward only during the printing process to be positioned above the substrate support 200. This is because, when the partition 452 is fixed to an upper portion of the substrate support 200, this may cause significant interference during other processes, such as a substrate fixing process, a substrate and electrode module alignment process, and a cleaning process other than the printing process.

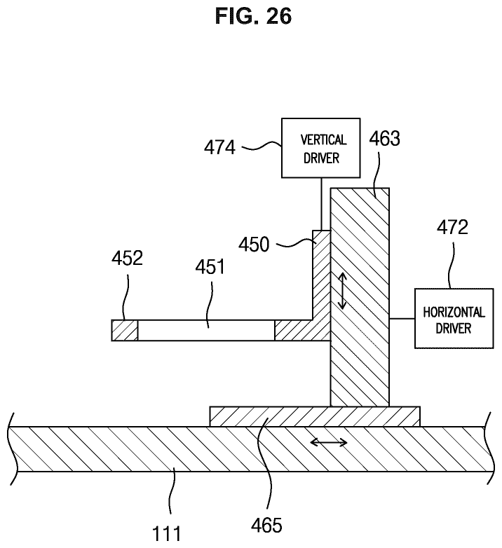

FIG. 26 is a schematic vertical cross-sectional view showing a fifth driver according to another embodiment of the present disclosure.

Referring to FIG. 26, the fifth driver 470 according to the present embodiment may be configured to enable the partition frame 450 to move horizontally and vertically forward and backward.

For example, the S-ECAM printing device 100 according to an embodiment of the present disclosure may include a vertical movement guide frame 463 that guides vertical movement of the partition frame 450, and a horizontal movement guide frame 465 that guides horizontal movement of the vertical movement guide frame 463, and the fifth driver 470 may include a horizontal driver 472 that horizontally moves the vertical movement guide frame 463, and a vertical driver 474 that vertically moves the partition frame 450.

Then, the controller 110 may control operations of the horizontal driver 472 and the vertical driver 474, and thus when the partition 452 is positioned above the substrate support 200, the partition 452 may be pushed toward the upper surface of the substrate support 200.

The substrate 130 is located above the substrate support 200, and thus as in the above embodiment, if the fifth driver 470 is configured to only allow the partition frame 450 to move horizontally, when the partition frame 450 moves horizontally, the partition frame 450 may be caught on the substrate 130, and thus it is difficult to push the partition frame 450 toward the upper surface of the substrate support 200.

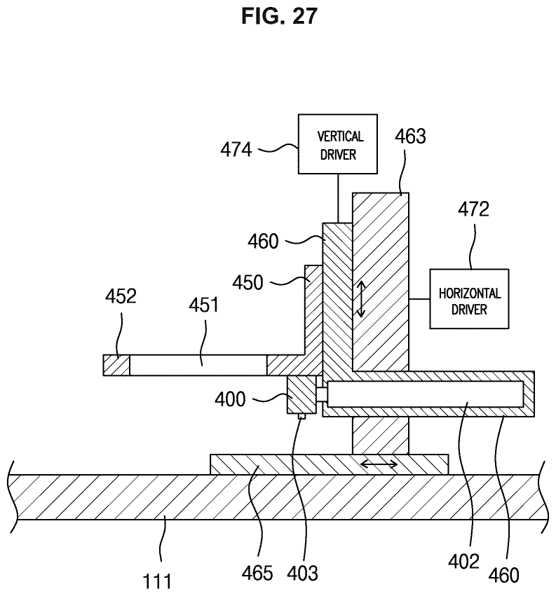

FIG. 27 is a schematic vertical cross-sectional view showing an S-ECAM printing device according to an embodiment of the present disclosure.

The S-ECAM printing device 100 according to the present embodiment may be configured to position the partition 452 above the substrate support 200 during the printing process and enable cleaning of the substrate 130 and the electrode module 300 after the printing process.

Referring to FIG. 27, the S-ECAM printing device 100 according to the present embodiment may include the cleaning block 400 that cleans the substrate 130 and the electrode module 300, the fourth driver 402 that moves the cleaning block 400, the partition frame 450 including the partition 452 that defines the space 451 in which the substrate 130 and the electrode 320 are immersed by the electrolyte discharged from the outlet 313 of the electrode module 300, and the fifth driver 470 that moves the partition frame 450. The controller 110 may control an operation of the fourth driver 402 to move the cleaning block 400 between the substrate 130 and the electrode module 300 and control an operation of the fifth driver 470 to position the partition 452 above the substrate support 200.

As described in the above embodiment, the fourth driver 402 may include a cylinder 402 that moves the cleaning block 400 horizontally forward.

In this case, the S-ECAM printing device 100 according to an embodiment of the present disclosure may include a bracket 460 to which the partition frame 450 and the cylinder 402 are fixed, the vertical movement guide frame 463 that guides vertical movement of the bracket 460, and the horizontal movement guide frame 465 that guides horizontal movement of the vertical movement guide frame 463, and the fifth driver 470 may include the horizontal driver 472 that horizontally moves the vertical movement guide frame 463 and the vertical driver 474 that vertically moves the bracket 460.

Then, the cleaning block 400 and the cylinder 402 may be moved horizontally and vertically together with the partition frame 450, and thus the overall configuration of the S-ECAM printing device 100 may be simplified.

When the cylinder 402 is fixed to the bracket 460 together with the partition frame 450, the cylinder 402 may be fixed to the bracket 460 to be located below the partition frame 450.

In this case, a height at which the cylinder 402 is fixed to the bracket 460 may be fixed at a height at which a lower portion of the partition frame 450 may be cleaned when the cleaning block 400 moves horizontally. For example, the cylinder 402 may be fixed at a height at which the upper surface of the cleaning block 400 is positioned on the bottom surface of the partition frame 450.

Then, when the controller 110 controls an operation of the vertical driver 474 to vertically move the partition frame 450 such that the bottom surface of the partition frame 450 is horizontal to the bottom surface of the electrode module 300 and then operates the cylinder 402 to horizontally move the cleaning block 400, the cleaning block 400 may simultaneously clean not only the upper portion of the substrate 130 and the lower portion of the electrode module 300, but also the lower portion of the partition frame 450 while horizontally moving between the substrate 130 and the electrode module 300.

The guide ball 403 may be provided at a lower portion of the cleaning block 400, and the support wall 127 that supports the guide ball 403 may be provided in the bath 120, as described above.

Hereinafter, a method of controlling an S-ECAM printing device according to an embodiment of the present disclosure will be described. Each operation of the control method may be performed by the controller 110.

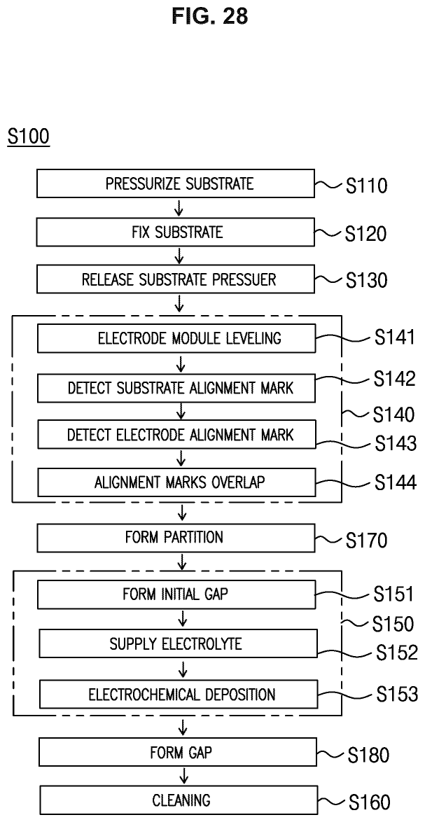

FIG. 28 is a diagram showing a method of controlling an S-ECAM printing device according to an embodiment of the present disclosure.

Referring to FIG. 28, a control method S100 of an S-ECAM printing device according to an embodiment of the present disclosure may include a substrate pressurizing operation S110 of controlling an operation of the third driver 153 such that the rod 152 located at one side of the bath 120 pressurizes the substrate 130 located above the substrate support 200.

The substrate pressurizing operation S110 may be performed when the proximity sensor 207 formed on the substrate support 200 detects the substrate 130.

The control method S100 may include a substrate fixing operation S120 of operating the vacuum pump 108 while the substrate 130 is pressurized to fix the substrate 130 through the vacuum hole 201 formed in the lower portion of the substrate support 200.

The control method S100 may include a substrate pressure release operation S130 of controlling an operation of the third driver 153 while the substrate 130 is fixed to release a pressurized state of the substrate 130 after the substrate fixing operation S120.

The control method S100 may include an alignment operation S140 of controlling operations of the first driver 101 and the second driver 107 to align the substrate 130 and the electrode module 300 after the substrate pressure release operation S130.

The alignment operation S140 may include an electrode module leveling operation S141 of controlling the operation of the first driver 101 according to detection by the gap sensor 307 provided in the electrode module 300 such that the bottom surface of the electrode module 300 is positioned in parallel to the upper surface of the substrate 130, a substrate alignment mark detection operation S142 of controlling the operation of the second driver 107 to move the camera module 140 such that the camera 142 provided in the camera module 140 detects the substrate alignment mark 144 formed on the substrate 130, an electrode alignment mark detection operation S143 of controlling the operation of the first driver 101 to move the electrode module 300 such that the camera 142 detects the electrode alignment mark 145 formed on the electrode module 300, and an alignment mark overlapping operation S144 of controlling the operation of the first driver 101 to move the electrode module 300 such that the electrode alignment mark 145 detected by the camera 142 overlaps the substrate alignment mark 144.

The control method S100 may include a printing operation S150 of controlling operations of the first driver 101, the power supply 102, and the pump 104 to electrochemically deposit metal ions included in the electrolyte on a predetermined area of the substrate 130, which faces the electrode 320 formed on the bottom surface of the electrode module 300, after the alignment operation S140.

The printing operation S150 may include an initial gap forming operation S151 of controlling the operation of the first driver 101 to lower the electrode module 300 such that a gap between the substrate 130 and the electrode 320 defines a preset initial gap, an electrolyte supply operation S152 of controlling the operation of the pump 104 to supply the electrolyte stored in the storage unit 103 to the inlet 312 formed in the electrode module 300, and an electrochemical deposition operation S153 of controlling an operation of the power supply 102 to electrochemically deposit metal ions included in the electrolyte on a predetermined area of the substrate 130, which faces the electrode 320, while the substrate 130 and the electrode 320 are immersed in the electrolyte discharged through the outlet 313 of the electrode module 300.

The preset initial gap may be a gap input by a worker through the input unit 105.

The control method S100 may include a cleaning operation S160 of controlling the operation of the fourth driver 402 to move the cleaning block 400 between the substrate 130 and the electrode module 300 after the printing operation.

The cleaning operation S160 may be performed by operating at least one of the vacuum pump 108 and the air compressor 109.

The control method S100 may include a partition forming operation S170 of controlling the operation of the fifth driver 470 to move the partition frame 450 including the partition 452 such that the partition 452 defining the space 451 in which the substrate 130 and the electrode 320 are immersed in the electrolyte is positioned above the substrate support 200.

The partition forming operation S170 may be performed before the alignment operation S140 or before the printing operation S150.

The control method S100 may include a gap forming operation S180 of controlling operations of the first driver 101 and the fifth driver 470 to vertically move the electrode module 300 and the partition frame 450 such that the electrode module 300 and the partition frame 450 are spaced apart from the substrate 130 by a preset gap before the cleaning operation S160.

The preset gap may be a gap corresponding to a thickness of the cleaning block 400, and the gap forming operation S180 may be performed to insert the electrode module 300 into the partition 452 such that the bottom surface of the electrode module 300 and the bottom surface of the partition frame 450 are positioned in parallel to each other.

As described above, the present disclosure relates to a selective electrochemical additive manufacturing (S-ECAM) printing device, and more particularly, to an S-ECAM printing device for selectively depositing a metal raw material on a substrate by using electrochemical additive manufacturing (ECAM), and the embodiment thereof may be changed in various forms. Therefore, the present disclosure is not limited to the embodiments disclosed in this specification, and all forms to be modified by those of skill in the art to which the present disclosure pertains are also within the scope of the present disclosure.

1. A selective electrochemical additive manufacturing (S-ECAM) printing device comprising:
a bath;
a substrate support provided in the bath and having a substrate located on the substrate support;
an electrode module including an electrode holder having an inlet through which electrolyte is introduced and an outlet through which the electrolyte introduced through the inlet is discharged, a plurality of electrodes provided at predetermined intervals on a bottom surface of the electrode holder, and a cover coupled to an upper portion of the electrode holder;
a power supply configured to supply power by using the electrode as an anode and the substrate as a cathode;
a storage unit storing electrolyte;
a pump supplying the electrolyte stored in the storage unit to the inlet; and
a controller configured to apply power to the power supply to electrochemically deposit metal ions included in the electrolyte on a predetermined area of the substrate, which faces the electrode, in a state in which the electrode and the substrate are immersed in the electrolyte discharged from the outlet of the electrode holder while being spaced apart from each other by a predetermined interval,
wherein an anode plate connected to an anode of the power supply and a cathode plate connected to a cathode of the power supply are fixed to the cover, and
the electrode holder includes an anode probe connecting the electrode and the anode plate to each other, and a cathode probe connecting the substrate and the cathode plate to each other.

2. The S-ECAM printing device of claim 1, wherein an anode probe hole into which the anode probe is inserted, a fixing groove into which the electrode is fixed at a lower end of the anode probe hole, and a cathode probe hole into which the cathode probe is inserted are formed in the electrode holder,
the anode probe is inserted into the anode probe hole such that a lower end of the anode probe is in contact with the electrode and an upper end of the anode probe is in contact with the anode probe to electrically connect the electrode and the anode plate to each other, and
the cathode probe is inserted into the cathode probe hole such that a lower end of the cathode probe protrudes below the electrode holder and is in contact with the substrate, and an upper end of the cathode probe is in contact with the cathode plate to electrically connect the substrate and the cathode plate to each other.

3. The S-ECAM printing device of claim 2, wherein the anode probe includes an anode probe body inserted into the anode probe hole, an anode upper contact portion coupled to an upper portion of the anode probe body and in contact with the anode plate, an anode lower contact portion coupled to a lower portion of the anode probe body and in contact with the electrode, an anode upper elastic member provided between the upper portion of the anode probe body and the anode upper contact portion to provide upward elasticity, and an anode lower elastic member provided between the lower portion of the anode probe body and the anode lower contact portion to provide downward elasticity.

4. The S-ECAM printing device of claim 2, wherein the cathode probe includes a cathode probe body inserted into the cathode probe hole, a cathode upper contact portion coupled to an upper portion of the cathode probe body and in contact with the cathode plate, a cathode lower contact portion coupled to a lower portion of the cathode probe body, protruding below the electrode holder, and in contact with the substrate, a cathode upper elastic member provided between the upper portion of the cathode probe body and the cathode upper contact portion to provide upward elasticity, and a cathode lower elastic member provided between the lower portion of the cathode probe body and the cathode lower contact portion to provide downward elasticity.

5. The S-ECAM printing device of claim 1, wherein the anode plate and the cathode plate are fixed to the cover with a height difference without being in contact with each other.

6. The S-ECAM printing device of claim 5, wherein a step portion and an accommodation groove are formed in the cover, and one of the anode plate and the cathode plate is fixed in a supported state on the step portion, and another one is fixed in an accommodated state on the accommodation groove.

7. The S-ECAM printing device of claim 2, wherein the electrode module includes at least three gap sensors,
a gap sensor hole into which the gap sensor is inserted and a connecting flow path connecting the inlet and the outlet to each other are formed in the electrode holder, and
an electrode alignment mark is formed on a bottom surface of the electrode holder.

8. An electrode module comprising:
an electrode holder having an inlet through which electrolyte is introduced and an outlet through which the electrolyte introduced through the inlet is discharged;
a plurality of electrodes provided at predetermined intervals on a bottom surface of the electrode holder;
a cover coupled to an upper portion of the electrode holder;
an anode plate fixed to the cover; and
a cathode plate fixed to the cover,
wherein the electrode holder includes an anode probe connecting the electrode and the anode plate to each other, and a cathode probe connected to the anode plate and protruding below the electrode holder.

9. The electrode module of claim 8, wherein an anode probe hole into which the anode probe is inserted, a fixing groove into which the electrode is fixed at a lower end of the anode probe hole, and a cathode probe hole into which the cathode probe is inserted are formed in the electrode holder,
the anode probe is inserted into the anode probe hole such that a lower end of the anode probe is in contact with the electrode and an upper end of the anode probe is in contact with the anode probe to electrically connect the electrode and the anode plate to each other, and
the cathode probe is inserted into the cathode probe hole such that a lower end of the cathode probe protrudes below the electrode holder, and an upper end of the cathode probe is in contact with the cathode plate.

10. The electrode module of claim 9, wherein the anode probe includes an anode probe body, an anode upper contact portion coupled to an upper portion of the anode probe body and in contact with the anode plate, an anode lower contact portion coupled to a lower portion of the anode probe body and in contact with the electrode, an anode upper elastic member provided between the upper portion of the anode probe body and the anode upper contact portion to provide upward elasticity, and an anode lower elastic member provided between the lower portion of the anode probe body and the anode lower contact portion to provide downward elasticity.

11. The electrode module of claim 10, wherein the anode probe body includes a wire electrically connecting the anode upper contact portion and the anode lower contact portion to each other.

12. The electrode module of claim 9, wherein the cathode probe includes a cathode probe body, a cathode upper contact portion coupled to an upper portion of the cathode probe body and in contact with the cathode plate, a cathode lower contact portion coupled to a lower portion of the cathode probe body and protruding below the electrode holder, a cathode upper elastic member provided between the upper portion of the cathode probe body and the cathode upper contact portion to provide upward elasticity, and a cathode lower elastic member provided between the lower portion of the cathode probe body and the cathode lower contact portion to provide downward elasticity.

13. The electrode module of claim 12, wherein the cathode probe body includes a wire electrically connecting the cathode upper contact portion and the cathode lower contact portion to each other.

14. The electrode module of claim 8, wherein the anode plate and the cathode plate are fixed to the cover with a height difference without being in contact with each other.

15. The electrode module of claim 14, wherein a step portion and an accommodation groove are formed in the cover, and one of the anode plate and the cathode plate is fixed in a supported state on the step portion, and another one is fixed in an accommodated state on the accommodation groove.

16. The electrode module of claim 15, wherein the cathode plate is fixed in a supported state on the step portion, and the anode plate is fixed in an accommodated state on the accommodation groove, and
a contact prevention hole is formed in the cathode plate to prevent the anode probe from being in contact with the cathode plate.

17. The electrode module of claim 15, wherein the anode plate is fixed in a supported state on the step portion, and the cathode plate is fixed in an accommodated state on the accommodation groove, and
a contact prevention hole is formed in the anode plate to prevent the cathode probe from being in contact with the anode plate.

18. The electrode module of claim 9, wherein the electrode module includes at least three gap sensors,
a gap sensor hole into which the gap sensor is inserted and a connecting flow path connecting the inlet and the outlet to each other are formed in the electrode holder, and
an electrode alignment mark is formed on a bottom surface of the electrode holder.
